(19) United States
(12) Patent Application Publication
(10) Pub. No.: US 2026/0254247 A1
(43) Pub. Date: Aug. 27, 2026

(54) DRILLING RIG POWER MANAGEMENT BASED ON THERMAL MONITORING OF ENERGY STORAGE

(71) Applicant: Schlumberger Technology Corporation, Sugar Land, TX (US)

(72) Inventors: Nick Paul Krippner, Katy, TX (US); Paul Wyman, Katy, TX (US); Mateo Garcia, Katy, TX (US); Alyssa Brown, Katy, TX (US)

(21) Appl. No.: 19/208,287

(22) Filed: May 14, 2025

Related U.S. Application Data
(60) Provisional application No. 63/761,286, filed on Feb. 21, 2025.

(51) Int. Cl. H02J 3/28; G01R 31/382; H01M 10/44

(52) U.S. Cl. CPC H02J 3/28; G01R 31/382; H01M 10/443; H02J 2101/10; H02J 2105/10

(57) ABSTRACT

A rig power management system identifies a power demand of a drilling rig and provides at least a portion of the power demand with a rig generator set (genset) of one or more generators, including operating the genset at an efficiency threshold of the genset. The system exchanges power with a battery energy storage system (BESS) at an average power transfer rate. When the power demand is greater than the efficiency threshold, the system supplements the genset with the BESS to meet the power demand. When the power demand is less than the efficiency threshold, the system maintains the genset at the efficiency threshold to charge the BESS with the genset. Based on receiving temperature data for the BESS, the system adjusts the average power transfer rate to an adjusted average power transfer rate and exchanges power with the BESS at the adjusted average power transfer rate.

This Application claims priority to and the benefit of U.S. Provisional Patent Application No. 63/761,286 filed on Feb. 21, 2025, which is hereby incorporated by reference in its entirety.

### BACKGROUND OF THE DISCLOSURE

Downhole drilling systems include multiple pieces of equipment. The equipment performs drilling activities, advancing a wellbore, reaming a wellbore, installing drill pipe, removing drill pipe, installing casing, grouting, pumping drilling fluid, performing administrative tasks, any other drilling activity, and combinations thereof. Electrical power may be supplied to the equipment in any manner. For example, a rig power supply system may include generators, grid power, battery power, and so forth. Electrical power may be a large expense and source of carbon emissions for a drilling system.

### SUMMARY

In some aspects, the techniques described herein relate to a method for rig power management. The method includes identifying a power demand of a drilling rig, and providing at least a portion of the power demand with a rig generator set (genset) of one or more generators, including operating the genset at an efficiency threshold of the genset. The method includes exchanging power with a battery energy storage system (BESS) at an average power transfer rate, including: when the power demand is greater than the efficiency threshold, supplementing the genset with the BESS to meet the power demand, or when the power demand is less than the efficiency threshold, maintaining the genset at the efficiency threshold to charge the BESS with the genset. The method includes adjusting the average power transfer rate to an adjusted average power transfer rate based on receiving temperature data associated with one or more energy cells of the BESS, and exchanging power with the BESS at the adjusted average power transfer rate. In some embodiments, the method is performed by a computer system. In some embodiments, the method is performed as instructions stored on a computer-readable storage medium.

This summary is provided to introduce a selection of concepts that are further described in the detailed description. This summary is not intended to identify key or essential features of the claimed subject matter, nor is it intended to be used as an aid in limiting the scope of the claimed subject matter. Additional features and aspects of embodiments of the disclosure will be set forth herein, and in part will be obvious from the description, or may be learned by the practice of such embodiments.

### BRIEF DESCRIPTION OF THE DRAWINGS

In order to describe the manner in which the above-recited and other features of the disclosure can be obtained, a more particular description will be rendered by reference to specific embodiments thereof which are illustrated in the appended drawings. For better understanding, the like elements have been designated by like reference numbers throughout the various accompanying figures. While some of the drawings may be schematic or exaggerated representations of concepts, at least some of the drawings may be drawn to scale. Understanding that the drawings depict some example embodiments, the embodiments will be described and explained with additional specificity and detail through the use of the accompanying drawings in which:

FIG. 1 is a representation of a drilling system for drilling an earth formation, according to at least one embodiment of the present disclosure.

FIG. 2 is a schematic representation of a rig power management system, according to at least one embodiment of the present disclosure.

FIG. 3 is a representation of a rig power management system, according to at least one embodiment of the present disclosure.

FIGS. 4-1 and 4-2 are example power generation plots illustrating power generation over time, according to at least one embodiment of the present disclosure.

FIG. 5 is a flowchart of a method for rig power management, according to at least one embodiment of the present disclosure.

FIG. 6 is a representation of a computing system, according to at least one embodiment of the present disclosure.

### DETAILED DESCRIPTION

This disclosure generally relates to a power management system for providing electrical power to a drilling system, including a drill rig, and other devices which operate based on electrical power. In many cases, the power demand, load, or power draw of a drilling system may change over time, such as transient changes (e.g., spikes, dips) or more gradual, steady-state changes. For example, during drilling operations, changes in drilling conditions, transitioning between different drilling operations, and other changes of the drilling rig may cause the power demand to vary. Accordingly, the power management system may adapt to the changing power needs of a drilling system in order to meet this variable power demand.

A drilling rig may receive power from a rig generator set (genset). While in some cases, gensets may be equipped to provide variable amounts of power to meet transient and/or gradual changes to the power demand, in some cases, generators may operate inefficiently and/or may experience damage or wear by varying or changing the amount of power they generate. In some cases, generators may even be incapable of adapting (e.g., quickly enough) to some variations in power demand, such as extreme transient changes in magnitude or duration. The power management system may include a battery energy storage system (BESS) to accompany the genset and to provide supplemental power to meet changing power demands. For instance, the BESS may be a battery storage system which may store a finite capacity of electrical energy, and which may discharge that energy in order to supplement the power provided by the genset. Accordingly, the power management system may be a hybrid system, and may advantageously charge and discharge the BESS, in addition to power generation with the genset, in order to meet the power demand of the drilling system.

In some cases, the generators of the genset may be characterized by an efficiency threshold at which the generators may operate most efficiently. For example, the efficiency threshold may be a threshold value or range of power output at which the generators can maximize the amount of electrical energy generated per unit of fuel. For instance, in some cases, the generators operate most efficiently at 75% (or other threshold) of a maximum power capacity of the generators.

In some embodiments, the power management system may facilitate operating the generators at the efficiency threshold, to the extent possible, in order to maximize the fuel efficiency of the power generated by the genset. To achieve this, the power management system may operate the genset at the efficiency threshold to meet the power demand of the drilling system, and changes to the power demand may be accommodated by the BESS. For instance, should the power demand increase above the genset efficiency threshold (e.g., for a transient period or a steady-state change) the BESS may discharge some or all of its power capacity to meet the increased load, thus maintaining the genset at the efficiency threshold. In another example, should the power demand decrease below the genset efficiency threshold, the genset may continue operating at the efficiency threshold, and the BESS may charge from the excess power.

In this way, the power management system may leverage the BESS in order to maximize the power generated by the genset per unit of fuel consumed by charging and discharging the BESS at opportune times. In some cases, the power management system may control a rate at which the BESS charges and discharges in order to prevent wear and/or damage to the BESS. For example, the power management system may monitor an average power transfer rate to and from the BESS over a monitoring period, and may limit or control the average rate at which the BESS charges and discharges in order to maintain the average power transfer rate within a threshold. For instance, the threshold for the average power transfer rate may be based on a C-rate for the energy cells of the BESS. Accordingly, the power management system may utilize the BESS as a supplement to the genset, and may do so within the limits of the average power transfer rate.

In some cases, the power management system monitors a temperature of the BESS, and adjusts the average power transfer rate based on the temperature. For example, elevated temperatures may cause wear or damage to the BESS, or worse, can lead to runaway thermal events, resulting in fires and/or explosions. Accordingly, the power management system may adjust (e.g., reduce) the average power transfer rate permitted for the BESS in order to maintain a working temperature of the BESS at or within a threshold temperature range. For instance, in some cases, the power management system may reduce the average power transfer rate to an adjusted average power transfer rate to manage the temperature of the BESS notwithstanding the (original) average power transfer rate being within one or more other ratings (e.g., a threshold C-rate) of the BESS, based on the BESS experiencing elevated temperatures.

In this way, the power management system may facilitate health of the BESS and safety of the drilling operation, for example, over potential efficiency gains at the genset. For instance, in some cases, adjusting the average power transfer rate based on the temperature of the BESS may result in the genset operating out of the efficiency threshold, such as above or below the efficiency threshold, in order to ensure that the temperature of the BESS is maintained within a safe operating range. In other cases, the power management system may bring additional generators of the genset online, or may take one or more generators offline based on an adjusted average power transfer rate of the BESS. Accordingly, the power management system may facilitate operating hybrid drill rig power systems both efficiently and based on thermal considerations.

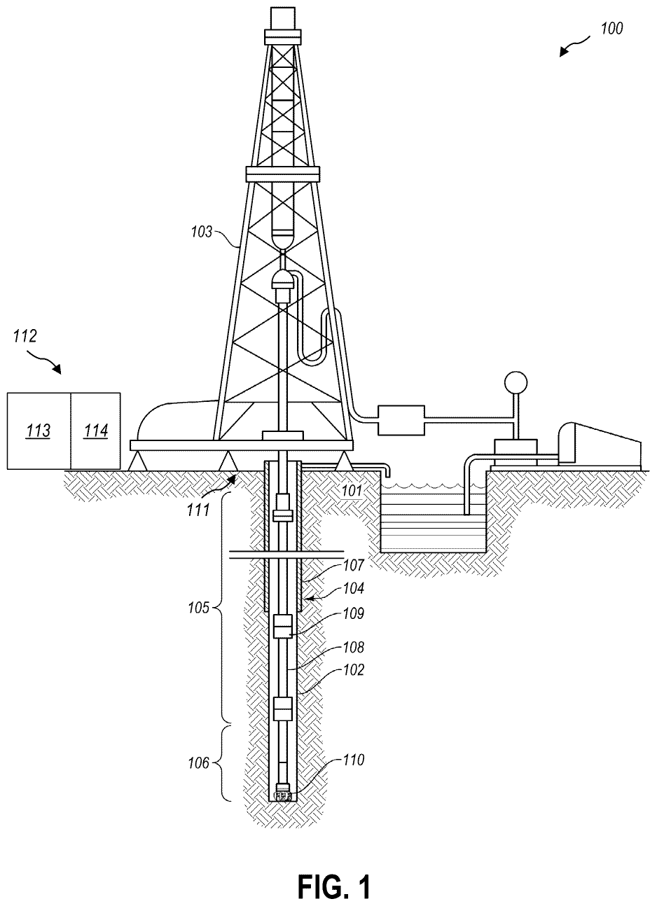

FIG. 1 shows one example of a drilling system 100 for drilling an earth formation 101 to form a wellbore 102. The drilling system 100 includes a drill rig 103 used to turn a drilling tool assembly 104 which extends downward into the wellbore 102. The drilling tool assembly 104 may include a drill string 105, a bottomhole assembly (“BHA”) 106, and a bit 110, attached to the downhole end of drill string 105.

The drill string 105 may include several joints of drill pipe 108 connected end-to-end through tool joints 109. The drill string 105 transmits drilling fluid through a central bore and transmits rotational power from the drill rig 103 to the BHA 106. In some embodiments, the drill string 105 may further include additional components such as subs, pup joints, etc. The drill pipe 108 provides a hydraulic passage through which drilling fluid is pumped from the surface 111. The drilling fluid discharges through selected-size nozzles, jets, or other orifices in the bit 110 for the purposes of cooling the bit 110 and cutting structures thereon, and for lifting cuttings out of the wellbore 102 as it is being drilled.

The elements of the drilling system 100 may be powered by a rig power supply system 112. The rig power supply system 112 may include a rig generator set (genset) 113 and a BESS 114. In some embodiments, one or more elements of the rig power supply system 112 are located on-site. For example, the rig power supply system 112 may be built and maintained at a location proximate to the drilling system 100, including on land owned or leased by the owner of the drilling system 100, within sight of the drilling system 100, or within an on-site distance of the drilling system 100. The on-site distance may be any distance, including 5 m, 10 m, 25 m, 50 m, 100 m, 250 m, 500 m, 1,000 m, 1,500 m, any other distance, and combinations thereof. In some embodiments, on-site power is power that is generated exclusively for the drilling system 100. In some embodiments, on-site power is power that is generated for the drilling system 100 and other drilling and/or hydrocarbon-processing systems located near the drilling system 100.

The genset 113 may include one or more generators. For example, the generators may be combustion engines powered by a combustion fuel such as diesel, gasoline, natural gas (or other gas such as propane), any other hydrocarbon, hydrogen, any other combustion fuel, and combinations thereof.

The BESS 114 may be an energy storage comprising one (and often many) battery-energy cells. For example, the BESS 114 may include a plurality of energy cells which may be configured in an architecture including one or more modules of multiple energy cells, and one or more racks of multiple modules. In some cases, the battery energy cells may be representative of a smallest individual energy storage unit or component of the BESS. In some embodiments the battery cells are lithium-ion battery cells, but may also include any other type of battery storage type and/or chemical makeup. The BESS 114 may be rechargeable and may store energy for use by the drilling system 100. For example, energy may be added to the battery cells of the BESS 114 and stored as chemical and/or potential energy. The BESS 114 may discharge the potential energy to convert it to electricity.

As discussed herein, during operation of the drilling system 100, the powered elements of the drilling system 100 may draw power from the rig power supply system 112 with a power demand, load, or power draw. The power demand may be the total amount of power drawn from the rig power supply system 112 by all of the electronic components of the drilling system 100. In some cases, the power demand fluctuates or varies. For example, changes in the operating status of the various components of the drilling system 100 may increase or decrease their respective power draw. As a particular example, changes in a formation that a drill string is interacting with, transitions between different operations of the drilling system 100, pauses or halts of a drilling operation, or other causes may result in the power draw changing. The changes may be transient such as large peaks or dips, or may be more gradual changes to the steady-state operation of the power demand.

In some embodiments, the rig power supply system 112 is configured to provide a variable power to the drilling system 100 to meet the variable demand. For example, the genset 113 may be operated to provide a baseline and/or steady state power, and any changes to this baseline (e.g., above or below the baseline) may be provided by the BESS 114. To elaborate, the genset 113 may have an efficiency threshold, which may be a power draw, load, or output of the generators that corresponds with a maximum efficiency of the generators. For example, the efficiency threshold may be an operating state of the generators which achieves a greatest fuel efficiency, or converts or produces the most amount of electrical power per unit of fuel. In some cases, the efficiency threshold may be between 70% and 80% of a maximum power capacity of the generators, such as 75% of the power capacity. For example, each generator of the genset 113 may have a power capacity of between 750 kW and 1250 kW, such as about 1000 kW. In some cases, the efficiency threshold may be a power output of 750 kW for each generator of the genset 113.

Operating one or more generators of the genset over the efficiency threshold may result in diminished returns, or may not net a proportional amount of power generated per additional unit of fuel consumed. The operating efficiency of the genset 113 may be a predetermined threshold, such as a threshold defined through a specification of the generators, through empirical observation, etc. In some embodiments, each generator of the genset 113 may have the same efficiency threshold, or one or more generators may have a different efficiency threshold. Similarly, operating below the efficiency threshold may also result in a reduced fuel efficiency. Accordingly, it may be advantageous to operate the genset to provide the power demand at the efficiency threshold, to the extent possible, for an extended period of time, or even indefinitely. In this way, operating the genset 113 at the efficiency threshold may decrease an operating cost of the drilling system 100, such as improving fuel consumption, carbon emission, operational expenditure, tool life, or other beneficial outcomes of the drilling system 100.

In some cases, the BESS 114 may be operated to provide supplemental or auxiliary power in addition to that of the genset 113 to provide power to the drilling system 100. For example, the BESS 114 may be advantageously utilized to maintain the genset 113 operating at the efficiency threshold, while accommodating for changes in the power demand (e.g., power demands greater or less than the efficiency threshold) with the BESS 114. As an illustrative example, in some cases, the power demand may increase over that which the genset 113 can provide at the efficiency threshold, and the BESS 114 may be utilized to discharge additional or supplemental energy to meet the power demand. To elaborate, in some cases the power demand may be between about 750 kW and 1250 kW, and the power demand may experience one or more increases and/or decreases. For example, a steady state of the power demand may increase (e.g., gradually and/or steadily) within the 750 kW-1250 kW range, or transient changes to the power demand may spike as high as 1.5 MW. Rather than ramp up power generation of the genset 113 (e.g., including bringing additional generators online) to meet this increased demand which in some cases can cause wear, damage, or inefficiencies of the genset 113, the genset 113 may be maintained at the efficiency threshold and the BESS 114 may be discharged to provide the additional power. In another example, the power demand may decrease below that which the genset 113 can provide at the efficiency threshold (e.g., such as transient drops as low as 0 W), and the genset 113 may be maintained at the efficiency threshold with the additional energy being input to the BESS 114 to charge the BESS 114.

The BESS 114 has an energy storage capacity, or an amount of electrical energy which can be stored by the battery cells of the BESS. For example, the energy storage capacity may be the capacity of energy storage in ampere-hours (Ah), Watt-hour (Wh), kilowatt-hours (kWh), Megawatt-hours (MWh), Gigawatt-hours (GWh), and so forth. In some cases, the energy storage capacity of the BESS is between 200 and 500 kWh, such as about 350 kWh. The BESS 114 may have a state of charge (SOC), which may be a representation of the amount of available and/or accessible energy in the BESS 114. In some embodiments, the SOC is a percentage of the total energy storage capacity of the BESS 114.

The BESS 114 may be characterized by a capacity rate or a C-rate, for example, based on the battery cells comprising the BESS. The C-rate may characterize a nominal rate at which energy can be stored or extracted from the BESS 114. For instance, a 1C rate may denote the rate at which the BESS 114 (e.g., the battery cells) can be fully charged or discharged in one hour. Similarly, a 2C rate is a rate at which the BESS 114 can be fully charged or discharged in 30 minutes, and a 3C rate, 20 minutes. To illustrate, for a BESS having an energy storage capacity of 350 kWh, the 1C rate would be a charge/discharge rate of 350 kW, the 2C rate, 700 kW, and the 3C rate, 1050 kW. Accordingly, a higher C-rate may be associated with higher performance (e.g., power output or charging). In some cases, a higher C-rate may cause an increase in temperature of the BESS 114 which, for prolonged durations may lead to the BESS reaching or surpassing a temperature threshold as described herein. Such elevated temperatures of the BESS may tend to wear or damage the battery components.

As mentioned, the drilling system 100 includes a BHA 106. The BHA 106 may include the bit 110 or other components. An example BHA 106 may include additional or other components (e.g., coupled between to the drill string 105 and the bit 110). Examples of additional BHA components include drill collars, stabilizers, measurement-while-drilling (“MWD”) tools, logging-while-drilling (“LWD”) tools, downhole motors, underreamers, section mills, hydraulic disconnects, jars, vibration or dampening tools, other components, or combinations of the foregoing. The BHA 106 may further include a rotary steerable system (RSS). The RSS may include directional drilling tools that change a direction of the bit 110, and thereby the trajectory of the wellbore. At least a portion of the RSS may maintain a geostationary position relative to an absolute reference frame, such as gravity, magnetic north, and/or true north. Using measurements obtained with the geostationary position, the RSS may locate the bit 110, change the course of the bit 110, and direct the directional drilling tools on a projected trajectory.

In general, the drilling system 100 may include other drilling components and accessories, such as special valves (e.g., kelly cocks, blowout preventers, and safety valves). Additional components included in the drilling system 100 may be considered a part of the drilling tool assembly 104, the drill string 105, or a part of the BHA 106 depending on their locations in the drilling system 100.

The bit 110 in the BHA 106 may be any type of bit suitable for degrading downhole materials. For instance, the bit 110 may be a drill bit suitable for drilling the earth formation 101. Example types of drill bits used for drilling earth formations are fixed-cutter or drag bits. In other embodiments, the bit 110 may be a mill used for removing metal, composite, elastomer, other materials downhole, or combinations thereof. For instance, the bit 110 may be used with a whipstock to mill into casing 107 lining the wellbore 102. The bit 110 may also be a junk mill used to mill away tools, plugs, cement, other materials within the wellbore 102, or combinations thereof. Swarf or other cuttings formed by use of a mill may be lifted to surface, or may be allowed to fall downhole.

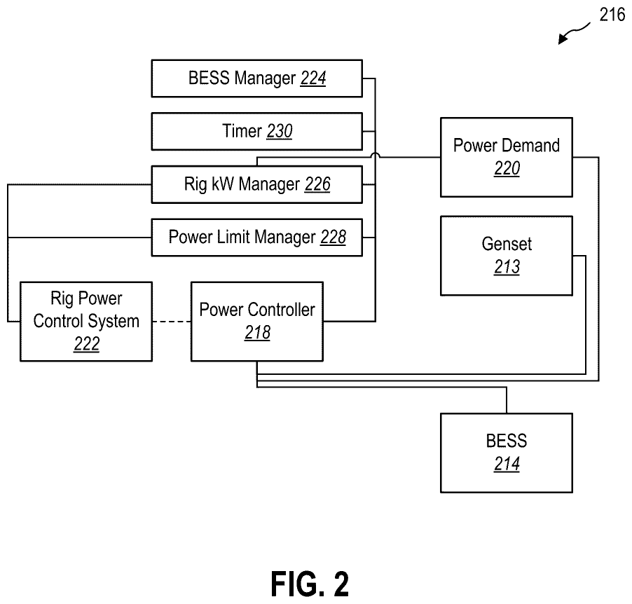

FIG. 2 is a schematic representation of a rig power management system 216, according to at least one embodiment of the present disclosure. The rig power management system 216 may include a power controller 218. As used herein, the power controller 218 may include any type of controller unit, such as a programmable logic controller (PLC), a personal computer (PC), an industrial PC, a digital control system (DCS), any other controller, and combinations thereof. The power controller 218 may manage the allocation of power of a genset 213 and a BESS 214 based on a rig power demand 220. The power controller 218 may control power at the genset 213 by instructing the genset 213 to start or stop one or more generators of the genset 213, including instructing the genset 213 to operate the generators at a given power output. For example, the power controller 218 may monitor the power demand 220 and, if the power demand 220 is greater than the power generation of the genset 213 and the BESS 214, then the power controller 218 may instruct the genset 213 to start or bring online one or more additional generators or connect an additional power source. In some examples, if the power demand 220 is less than the power generation of the genset 213, then the power controller 218 may instruct the genset 213 to turn off or take offline one or more generators. In this manner, operating the genset 213 may include operating the genset 213 at less than an entirety of the total number of generators.

The rig power management system 216 may include a rig power control system 222. The rig power control system 222 may control the operation of the genset 213. For example, the rig power control system 222 may regulate the rotational rate (e.g., in rotations per minute, RPM) of the generators of the genset 213, the frequency of the generators of the genset 213, the voltage of the generators of the genset 213, power output of the generators of the genset 213, control the load balance between the generators of the genset 213, and so forth. In some embodiments, the rig power control system 222 is independent from the power controller 218. For example, the power controller 218 may control which of the generators are activated, and the rig power control system 222 may control the operation of the activated generators. In some cases, the rig power control system 222 is implemented as part of the power controller 218. In some embodiments, the rig power control system 222 is a third-party controller. For example, the rig power control system 222 may be provided by the manufacturer of the genset 213. Maintaining the power controller 218 separate from the rig power control system 222 may facilitate a reduction in the processing load on the power controller 218. This may improve the responsiveness of the power controller 218 to changes in the power demand 220. In this manner, the power controller 218 may operate in real-time or near real-time to respond to sudden changes in the power demand 220.

The power controller 218 may include various managers, monitoring devices (e.g. communication modules, input/output modules, power monitoring devices, etc.), or other controllers (e.g. PLCs, remote PLC couplers, PC, industrial PCs, BESS 214 etc.) that monitor and provide input to determine which of the generators of the genset 213 to connect, turn on, and/or bring online. For example, the power controller 218 may include a BESS manager 224. The BESS manager 224 may be in communication with the BESS 214 and may monitor the SOC of the BESS 214. The BESS manager 224 may monitor any aspect of the SOC, including the SOC as a percentage of the energy storage capacity, the SOC as an amount of stored energy, the rate of change of the SOC (e.g., the rate of discharge, the rate of charging), the SOC of different portions of the BESS 214 (e.g., different cells, modules, or racks within the BESS 214), any other aspect of the SOC of the BESS 214, and combinations thereof. The power controller 218 may utilize the SOC to manage the operation of the genset 213. For example, if the power demand 220 is less than the efficiency threshold of the number of currently operating generators and the SOC of the BESS 214 is less than a SOC threshold, then the power controller 218 may connect the genset 213 to the BESS 214 to cause the genset 213 to charge the BESS 214. This may maintain the power demand 220 within the efficiency threshold of the genset 213 while increasing the SOC of the BESS 214. In some examples, the power demand 220 may increase above the efficiency threshold of the genset 213 and the BESS 214 may be above the SOC threshold. In this situation, the BESS 214 may supplement the power generation of the genset 213 with the BESS 214. This may allow the genset 213 to stay within the efficiency threshold for longer without adding an additional generator (which may cause all of the generators of the genset 213 to operate outside of the efficiency utilization).

The power controller 218 may further receive power consumption information from a rig kW manager 226. The rig kW manager 226 may receive information related to the power demand 220 from any location. For example, the rig kW manager 226 may receive power demand information by monitoring the outgoing power from the genset 213. In some examples, the rig kW manager 226 may receive power demand information from the rig power control system 222. In some examples, the rig kW manager 226 may receive power demand information from the genset 213. In some examples, the rig kW manager 226 may include multiple power monitors that may monitor the power draw from individual components that generate the power demand 220. In some examples, the rig kW manager 226 may be connected to a rig management system to identify which pieces of equipment are operating and their respective applied load. The power controller 218 may receive the power draw from the rig kW manager 226 to determine the power demand 220 on the drilling system. As discussed herein, the power controller 218 may use the power demand 220 to make decisions regarding the number of gensets 213 operating and the operation of the BESS 214 with respect to the genset 213 (e.g., supplementing power to the genset 213, receiving charge from the genset 213).

The power controller 218 may further include a power limit manager 228. The power limit manager 228 may monitor the power limit of the genset 213. The power limit may be the maximum amount of power that the genset 213 can output before failure and/or damage to the genset 213. As discussed herein, the power demand 220 may fluctuate, at times in an unpredictable manner. The power limit manager 228 may work with or permit without interfering with the rig power control system 222 to maintain sufficient capacity in the power generation of the genset 213 to provide power during a power fluctuation. In some embodiments, the power limit manager 228 may help to determine the efficiency threshold of the genset 213. The power limit manager 228 may be in communication with the rig power control system 222 to manage operation of the genset 213.

In some cases, the power controller 218 may be in communication with a timer 230. The timer 230 may facilitate monitoring, measuring, and/or controlling one or more features over one or more monitoring periods. For example, in some cases, the power controller 218 takes (e.g., time-series) measurement data over a monitoring period to characterize the energy output of the genset 213, the power transfer to and/or from the BESS 214, etc. In some cases, the power controller 218 monitors the power status and/or identifies a power profile or a power supply pattern of one or more components of the rig power management system 216 over a monitoring period. In some cases, the power controller 218 monitors one or more aspects over a rolling or updating monitoring period, such as taking a rolling average over an advancing period of time of a set duration.

In some embodiments, the monitoring period may be in a range having an upper value, a lower value, or upper and lower values including any of 1 sec, 1 min., 2 min, 5 min., 10 min., 15 min., 20 min., 25 min., 30 min., 35 min., 40 min., 45 min., 50 min., 55 min., 1 hour, 1.5 hours, 2 hours, 3 hours, 4 hours, 6 hours, 9 hours, 12 hours, 18 hours, 1 day, 2 days, 3 days, 1 week, 1 month, 1 year or any value therebetween. For example, the monitoring period may be greater than 1 sec. In another example, the monitoring period may be less than 1 year. In yet other examples, the monitoring period may be any value in a range between 1 sec. and 1 year. In some embodiments, it may be critical that the monitoring period is between 15 min. and 45 min. to use the past performance of the rig power management system 216 to manage the power system of the rig power management system 216. For example, as described herein, an average power transfer rate may be monitored and controlled for the BESS based on a rolling monitoring period to ensure that the BESS operates within a given temperature threshold.

The power controller 218 may monitor any aspect of the power status of the rig power management system 216 over one or more monitoring periods to identify power profiles or power supply patterns. For example, the power controller 218 may monitor the power demand 220 over time. The power controller 218 may receive the power demand 220 over time from the rig kW manager 226. The power controller 218 may identify any type of power supply pattern, including the average power demand 220, increases in the power demand 220, decreases in the power demand 220, fluctuation patterns in the power demand 220, any other trends in the power demand 220, and combinations thereof. The power controller 218 may receive the analysis of the power demand 220, including the power supply pattern, and determine how to place the genset 213 within the efficiency utilization and/or determine how to extend the amount of time the genset 213 is maintained within the efficiency utilization by adjusting the timer 230. For example, the power controller 218 may determine that, based on the power supply pattern, the genset 213 may be maintained within the efficiency utilization for an additional period of time by supplementing power generation with the BESS 214. In some examples, the power controller 218 may determine that, based on the existing patterns identified by the power controller 218, the genset 213 may be maintained within the efficiency utilization for an additional period of time by charging the BESS 214. In some cases, the power controller 218 may identify, based on a monitoring period, an average power transfer rate at which power is exchanged with the BESS. In some cases, the power controller 218 may adjust, limit, or control the (e.g., instantaneous) power transfer rate of the BESS in order to maintain the BESS within a given average power transfer rate as determined over a monitoring period. As discussed herein, in some cases, the power controller 218 may adjust, limit, or control the average power transfer rate, such as reducing the average power transfer rate, in order to manage thermal conditions of the BESS. In this way, the power controller 218 may manage one or more aspects with respect to one or more monitoring periods in order to increase the operating efficiency of the rig power management system 216, as well as to promote health and safety of the various components.

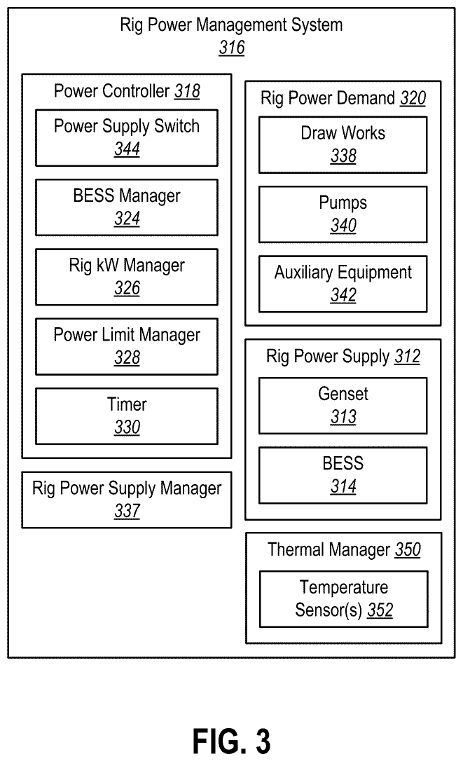

FIG. 3 is a representation of a rig power management system 316, according to at least one embodiment of the present disclosure. Each of the components of the rig power management system 316 can include software, hardware, or both. For example, the components can include one or more instructions stored on a computer-readable storage medium and executable by processors of one or more computing devices, such as a client device or server device. When executed by the one or more processors, the computer-executable instructions of the rig power management system 316 can cause the computing device(s) to perform the methods described herein. Alternatively, the components can include hardware, such as a special-purpose processing device to perform a certain function or group of functions. Alternatively, the components of the rig power management system 316 can include a combination of computer-executable instructions and hardware.

Furthermore, the components of the rig power management system 316 may, for example, be implemented as one or more operating systems, as one or more stand-alone applications, as one or more modules of an application, as one or more plug-ins, as one or more library functions or functions that may be called by other applications, and/or as a cloud-computing model. Thus, the components may be implemented as a stand-alone application, such as a desktop or mobile application. Furthermore, the components may be implemented as one or more web-based applications hosted on a remote server. The components may also be implemented in a suite of mobile device applications or “apps.”

The rig power management system 316 may manage the power distribution of a rig power supply 312. The rig power supply 312 may include any power source that provides power to a drilling rig. For example, the rig power supply 312 may include a genset 313 of one or more generators and a BESS 314 as described herein. In some cases, the rig power supply 312 may also include one or more other power sources, such as grid power, renewable power sources, or other types of energy storage systems, which may store energy in other forms. A rig power supply manager 337 may manage the operation of the individual elements of the rig power supply 312. For example, the rig power supply manager 337 may manage the operation of the generators of the genset 313, including managing load, frequency, RPM, any other aspect of the generators, and combinations thereof. In some examples, the rig power supply manager 337 may manage the operation of any other element of the rig power supply 312, including managing local voltage transformation and distribution of grid power and/or renewable power sources.

The rig power management system 316 may monitor a rig power demand 320. The rig power demand 320 may originate from any source or equipment on the drilling rig. A non-exhaustive list of examples of drilling equipment may include a draw works 338, drilling fluid pumps 340, auxiliary equipment 342, any other drilling equipment, and combinations thereof.

In some embodiments, a rig power supply manager 337 manages the operations of individual rig equipment. For example, the rig power supply manager 337 may adjust the operation of one or more individual rig components to adjust the power demand. In some examples, the rig power supply manager 337 may reduce the speed of the draw works 338. In some examples, the rig power supply manager 337 may reduce the volume of mud pumped downhole by slowing down the pumps.

The rig power management system 316 may further include a power controller 318. The power controller 318 may manage which of the elements of the rig power supply 312 are connected to and provide power to supply the rig power demand 320. For example, the power controller 318 may include a power supply switch 344. The power supply switch 344 may be connected to the rig power supply 312 and may switch a connection of the rig power supply 312 to connect or disconnect an element of the rig power supply 312 to supply the rig power demand 320.

In some embodiments, the power supply switch 344 connects different elements of the rig power supply 312 to the rig power demand 320. For example, the power supply switch 344 may connect the genset 313 and/or the BESS 314, or any other power source, and combinations thereof. As a specific, non-limiting example, the power supply switch 344 may facilitate connecting the genset 313 to provide a steady-state power, and may facilitate connecting the BESS 314 to provide supplemental power to accommodate changes to the steady-state power provided by the genset 313.

In some embodiments, the power supply switch 344 may connect different components of the same type of rig power supply 312. For example, the genset 313 may include multiple different generators. As the rig power demand 320 increases, the power supply switch 344 may connect additional generators to provide power for the rig power demand 320. As the rig power demand 320 decreases, the power supply switch 344 may disconnect one or more of the generators to increase the operating efficiency of the individual generators of the genset 313.

Each component of the rig power supply 312 may have an efficiency threshold. The efficiency threshold may be a utilization at which the particular component operates efficiently. For example, the genset 313 may have an efficiency threshold that may result in an efficient electrical power generation, as calculated by volume of fuel per unit at the electrical power generate value (e.g., kW per gallon/liter) as described herein. In some cases, the BESS 314 may have a particular SOC or SOC range at which the charge/discharge rate is increased and/or at which the charge/discharge sequence may reduce the degradation of the battery. In some cases, the BESS 314 may have a specific temperature or temperature range within which the battery cells of the BESS 314 operate most efficiently. In some cases, the BESS 314 may have a threshold temperature or critical temperature (or range) at which the battery cells may begin to degrade, wear, become damaged, or experience thermal runaway.

In accordance with at least one embodiment of the present disclosure, the power controller 318 may control which elements of the rig power supply 312 are connected to provide the rig power demand 320. To identify which elements of the rig power supply 312 to connect and/or disconnect, the power controller 318 may utilize one or more analysis managers. For example, the power controller 318 may include a rig kW manager 326. The rig kW manager 326 may monitor the power draw on the rig power demand 320 to determine how much power the rig power supply 312 is to supply. In some embodiments, the rig kW manager 326 may communicate with the rig power supply manager 337 to determine the power draw by the rig power demand 320. The power controller 318 may further include a power limit manager 328 that may analyze the power limit for the various elements of the rig power supply 312 and maintain a buffer to prevent the power limit from being exceeded by variations in the rig power demand 320. The power controller 318 includes a timer 330, which may facilitate analyzing or determining one or more trends, rates, and/or averages.

The power controller 318 includes a BESS manager 324, which may monitor and manage various aspects of the BESS 314. For example, the BESS manager 324 may monitor the SOC of the BESS 314. If the SOC of the BESS 314 is below an SOC threshold, the power supply switch 344 may cause the other elements of the rig power supply 312 to charge the BESS 314. If the BESS 314 is above the SOC threshold, the power controller 318 may permit the BESS 314 to provide power to satisfy the rig power demand 320 as needed.

In some cases, the power controller 318 (e.g., via the BESS manager 324), monitors a power transfer rate of the BESS 314. For example, the power transfer rate may be a rate (e.g., in kW, C-rate, or similar) at which power is exchanged with the BESS 314 at a given moment, or an instantaneous power transfer rate. The BESS manager 324 may control the exchange of power with the BESS 314 such that the instantaneous power transfer rate does not exceed one or more thresholds. For example, as described herein, the BESS 314 may be rated or specified based on a 1C rate, and the BESS 314 may also be rated to exceed that 1C rate to various degrees. For example, in some cases the BESS 314 may be capable of exchanging power at a 2C rate. In another case, the BESS 314 may be configured to exchange power at a 3C rate. The BESS manager 324 may monitor and control the instantaneous power transfer rate such that the BESS 314 does not exceed a threshold C-rate (e.g., 2C or 3C) for any given instance.

In some cases, the BESS manager 324 may monitor and/or determine an average power transfer rate for the BESS 314. For example, over a monitoring period, the BESS manager 324 may determine an average rate of power exchange with (e.g., to and from) the BESS 314. In some cases, the BESS manager 324 controls or limits the instantaneous power transfer rate (for one or more moments or periods of time) in order to maintain the average power transfer rate within a given threshold. For example, while the BESS 314 may be rated to exceed its 1C rate for power transfer, exceeding that 1C rate repeatedly and/or for an extended duration may damage, wear, or adversely increase the temperature of the BESS 314. Accordingly, the BESS manager 324 may limit the extent that the BESS 314 performs at these elevated rates (e.g., at higher C-rates) based on an average power transfer rate. For example, in some cases, the average power transfer rate, or a threshold thereof, may be a C-rate of 1.2 for the BESS 314. For instance, the average power transfer rate at a C-rate of 1.2, in some cases, has been observed through empirical testing to provide a balanced threshold for both performance and (e.g., thermal) health of the BESS 314.

The BESS manager 324 may monitor and/or limit the power transfer of the BESS 314 such that the average power transfer rate for a given monitoring period remains at or below a specified average rate (e.g., 1.2 C-rate). As an illustrative example, the BESS 314 may be permitted to operate at a higher C-rate, such as a 2C or 3C rate, for a period of time, which may tend to raise the average power transfer rate. In order to maintain the average power transfer rate of the BESS 314 at or below the threshold (e.g., 1.2C), the BESS manager 324 may limit the BESS 314 to operating at a lower C-rate, such as below a 1C rate in order to maintain the desired average. In another example, such as during periods of low or no activity, the average power transfer rate of the BESS 314 may tend to fall below a desired threshold, and the BESS manager 324 may control the BESS 314 to operate at a higher instantaneous power transfer rate in order to maintain the average power transfer rate at the threshold. In this way, the BESS manager 324 may promote a health of the BESS 314 by maintaining the average operation of the BESS 314 within a threshold average power transfer rate, which may be a value or range of values.

In some cases, the BESS manager 324 monitors one or more temperatures of the BESS 314. For example, the rig power management system 316 may include a thermal manager 350, which may monitor one or more temperature sensors 352. The temperature sensors 352 may include any thermal or temperature-measuring device. For example, the temperature sensors 352 may include one or more thermocouples, resistance temperature detectors (RTDs), thermistors, infrared sensors, thermopiles, semiconductor based sensors, or any other thermal device and combinations thereof. The temperature sensors 352 may be implemented at the BESS 314 and may measure one or more temperatures of the BESS 314. For example, one or more temperature sensors 352 may be implemented at one or more cells, modules, or racks of the BESS 314 to take one or more corresponding temperature measurements. For instance, in some cases, the thermal manager 350 monitors an operating temperature of the BESS 314 at a battery-cell level, such as monitoring the temperature of one or more (or all) of the individual battery cells. In some cases, the thermal manager 350 monitors a temperature of one or more modules of the BESS 314, which may comprise multiple battery cells, or an average cell temperature for a module. In various cases, the thermal manager 350 monitors a temperature of one or more (or all) racks of the BESS 314, comprising multiple modules, such as an average module temperature of a rack.

According to one or more embodiments of the present disclosure, the thermal manager 350 monitors one or more of these temperatures individually, and in some cases may make one or more determinations, inferences, or predictions regarding temperature. For example, the thermal manager 350 may determine an average or other statistical calculation of the temperature, such as an average cell temperature, an average module temperature, an average rack temperature, or an average overall temperature of the BESS 314. Any of these averages may be determined over a (e.g., rolling) monitoring period as described herein. In some cases, the thermal manager 350 determines a rate of change of one or more temperatures. For example, in addition to determining a (e.g., instantaneous) temperature, the thermal manager 350 may determine how the temperature is changing over time, such as over the monitoring period, or over a smaller (more recent) discrete time window. In this way, the thermal manager 350 may facilitate characterizing the utilization and health of the BESS 314.

The BESS manager 324 may receive temperature information from the thermal manager 350. In some cases, the BESS manager 324 may implement one or more limits to the BESS 314 based on the temperature of the BESS 314. For example, the BESS 314 (e.g., the battery cells) may have a specific temperature rating or specification. For instance, the BESS 314 may be rated to operate within a specific temperature range. In other cases, a temperature threshold or critical temperature may be a temperature at or above which the BESS 314 may experience wear, damage, or thermal runaway. In other examples, the BESS 314 may be characterized by a lower temperature limit, below which the battery cells may experience wear, damage, or decreased efficiency. The BESS 314 may tend to exhibit changes in temperature at, near, and/or approaching a limit based on an age, usage, duty cycle, or environment of the BESS 314. For instance, the BESS 314 may tend to exhibit elevated temperatures based on operating at higher power transfer rates, based on an age or wear of the battery cells, based on operating in a hotter environment, etc. The BESS 314 may experience lower temperatures during periods of low or no activity, or when implemented in colder environments.

In some cases, the BESS manager 324 may adjust, update, or modify the average power transfer rate (e.g., a threshold thereof) based on one or more temperatures of the BESS. For example, the BESS manager 324 may adjust the average power transfer rate of the BESS 314 in order to control, react to, mitigate, or influence one or more temperatures of the BESS, for example, to prevent damage or inefficiencies of the BESS 314. As an illustrative example, the BESS manager 324 may observe an elevated temperature of the BESS 314, and may adjust the average power transfer rate to an adjusted average power transfer rate, which may be a reduced power transfer rate. Similarly, in other examples, the BESS manager 324 may adjust the average power transfer rate to an adjusted power transfer rate that is an increased power transfer rate, for example, based on observing a reduced temperature of the BESS 314.

In other examples, the BESS manager 324 may observe that the rate of change of the temperature of the BESS 324 is trending at a (e.g., instantaneous) rate of change that exceeds a threshold rate of change, and the BESS manager 324 may adjust the average power transfer rate to an adjusted power transfer rate such that the (e.g., instantaneous) rate of change is within a threshold rate of change. For instance, the BESS manager 324 may observe that one or more temperatures of the BESS 324 is increasing at a rate that exceeds a threshold rate of change for the one or more temperatures, and the BESS manager 324 may adjust the average power transfer rate to an adjusted power transfer rate that is a reduced power transfer rate. Further, the BESS manager 324 may observe that one or more temperatures of the BESS 314 is decreasing at a rate that exceeds a threshold rate of change for the one or more temperatures, and the BESS manager 324 may adjust the average power transfer rate to an adjusted power transfer rate that is an increased power transfer rate.

In this way, the power controller 318 may actively monitor and manage power generation of the rig power supply 312, but may do so (e.g., via the BESS manager 324) based on thermal considerations of the BESS 314 in order to promote a safety and health of the BESS 314. For example, in some cases, operation of the genset may be controlled or adjusted in order to facilitate managing the temperature of the BESS. Various example scenarios of operating the rig power supply 312 in this way are illustrated and described in connection with FIGS. 4-1 and 4-2 below.

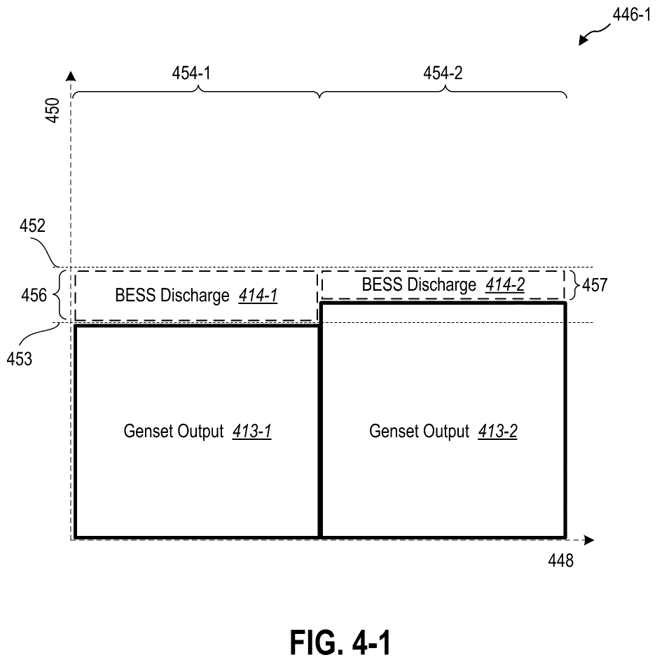

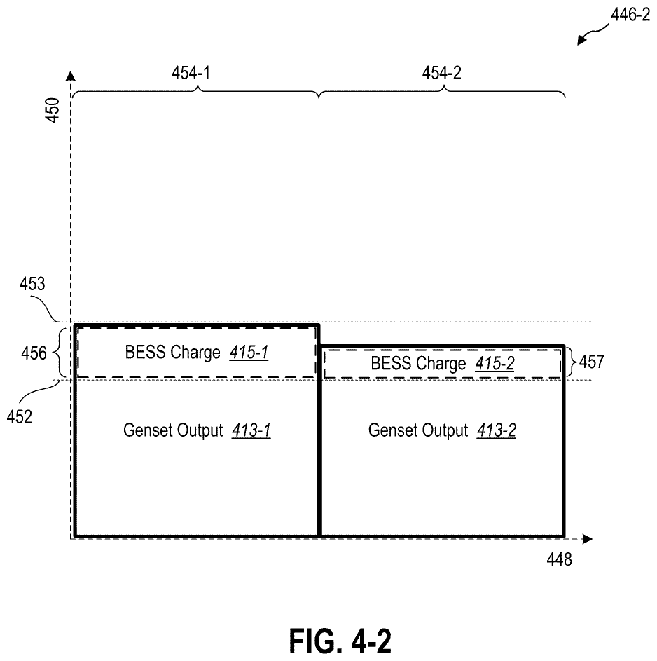

FIG. 4-1 is a representation of a first power generation plot 446-1 having time 448 on the x-axis (e.g., horizontal axis) and power 450 on the y-axis (e.g., vertical axis). The first power generation plot 446-1 indicates a power demand 452. The power demand 452 may represent the total power demand of the drilling system. Over a first period 454-1, power, to meet the power demand 452 may be supplied by a genset output 413-1, corresponding to the output of one or more generators of a genset during the first period 454-1. While operating in the first period 454-1, the genset output 413-1 may be operating at or near an efficiency threshold 453 of the genset as described herein. In this way, the genset output 413-1 may correspond with the efficiency threshold 453, or an increased (e.g., maximum) efficiency of the genset.

As shown, the power demand 452 may be greater than the efficiency threshold 453, and a BESS discharge 414-1 may be operated in addition to the genset output 413-1 in order to meet the power demand 452. The BESS discharge 414-1 may correspond with a power provided by a BESS as described herein during the first period 454-1. The BESS discharge 414-1 may be a discharge of the BESS in accordance with an average power transfer rate 456 of the BESS. The average power transfer rate 456 may be a rate at which the BESS transfers power from the BESS over a monitoring period as described herein. The BESS discharge 414-1 as shown in relation to the average power transfer rate 456 may be representative of the BESS discharge 414-1 being at, within, or less than a set value or threshold for the average power transfer rate 456.

In some cases, a BESS manager may observe that the temperature of the BESS is at, above, near, or approaching an upper temperature limit or a critical temperature threshold. For example, the temperature of the BESS may tend to increase based on any number of factors such as operating the BESS in a hotter environment, operating the BESS at higher energy transfer rates, an age or degradation of the BESS, and others. Accordingly, based on identifying the temperature of the BESS (e.g., an instantaneous temperature, an average temperature of a monitoring period, a rate of change of the temperature, etc.) in relation to a temperature threshold, the BESS manager may adjust the average power transfer rate 456 to an adjusted average power transfer rate 457, which may be a reduced power transfer rate in order to lower the temperature of the BESS, or maintain the temperature of the BESS below a given threshold. For example, the BESS manager may reduce or limit an instantaneous power transfer rate of the BESS such that the average power transfer rate 456 is reduced to the adjusted (reduced) average power transfer rate 457. Accordingly, during a second period 454-2, a BESS discharge 414-2 may be operated, which may be less than the BESS discharge 414-1.

In some cases, operating the BESS discharge 414-2 based on the adjusted average power transfer rate 457 may have the effect of increasing the output of the genset. For example, a genset output 413-2 for the second period 454-2 may be greater than the genset output 413-1 in order to meet the power demand 452 and based on the reduced BESS discharge 414-2 during the second period. As shown, in some cases, this may result in the genset output 413-1 departing from the efficiency threshold 453, such as surpassing the efficiency threshold 453 (e.g., for an active quantity and/or configuration of the generators of the genset). In some cases, another generator may be brought online to provide the genset output 413-1, which may cause each of the generators to operate below their respective efficiency thresholds. In any case, the genset output 413-1 may correspond with the genset being operated outside of the associated efficiency threshold 453.

As described above, it may generally be advantageous to operate the genset (e.g., indefinitely and/or for an extended period to the extent possible) at the efficiency threshold 453, and the BESS discharge 414-1 may accordingly be determined and/or implemented based on a difference between the power demand 452 and the efficiency threshold 453. For instance, in many cases, operation in this way may achieve an increased or maximum efficiency of the genset and the rig power management system as a whole. However, based on the temperature data of the BESS, in some cases it may be beneficial or necessary to adjust the average power transfer rate 456 as just discussed, in order to manage the thermal condition of the BESS, which may result in the genset operating outside of the efficiency threshold 453. For instance, in some cases, (e.g., elevated) temperatures of the BESS outside of one or more temperature thresholds may cause damage to the BESS, may present safety hazards, and/or may lead to runaway thermal events. Accordingly, in some cases, the temperature of the BESS may be prioritized at the expense of genset efficiency in order to avoid these undesirable outcomes for the BESS.

In some cases, the BESS discharge 414-2 may be adjusted to the adjusted power transfer rate 457 in this way notwithstanding the BESS operating within its (original) average power transfer rate 456 and/or operating within its rated or specified C rate. For example, in some cases, the BESS increasing in temperature may not necessarily be due to the BESS malfunctioning or exceeding some threshold average power transfer rate (e.g., average of 1.2C), but rather, other factors as mentioned above may cause the temperature of the BESS to increase. Accordingly, while the average power transfer rate 456 (e.g., alone) may be operable in some cases to manage the operation of the BESS within safe or operable limits, in some cases the BESS may be better monitored, managed, and protected, through monitoring of the temperature of the BESS and adjusting the average power transfer rate 456 as needed. For instance, the average power transfer rate 456 may in some cases lead to BESS temperatures of undesirable levels, and the BESS manager may adjust (e.g., reduce) the average power transfer rate to respond to the temperature of the BESS. Additionally, while in some situations the genset may be operated (e.g., together in conjunction with the BESS) to maintain the genset at or near the efficiency threshold 453, in some cases, it may be advantageous or necessary to operate the genset outside of the efficiency threshold 453 in order to maintain or prioritize a temperature of the BESS as described.

FIG. 4-2 is a representation of a second power generation plot 446-2 having time 448 on the x-axis (e.g., horizontal axis) and power 450 on the y-axis (e.g., vertical axis). The second power generation plot 446-2 includes a power demand 452. The power demand 452 may represent the total power demand of the drilling system. Over a first period 454-1, power, to meet the power demand of the power demand 452 may be supplied by a genset output 413-1. The genset output 413-1 may be operated at an efficiency threshold 453, which may be greater than the power demand 452. In order to meet or match the power demand 452, a BESS charge 415-1 may be operated, corresponding with a BESS receiving power from the genset output 413-1 in excess of the power demand 452. The BESS charge 415-1 may be operated at or within an average power transfer rate 456.

In some cases, a BESS manager may observe that the temperature of the BESS is at, above, near, or approaching an upper temperature limit or a critical temperature threshold. Based on identifying the temperature of the BESS in relation to a temperature threshold, the BESS manager may adjust the average power transfer rate 456 to an adjusted average power transfer rate 457, which may be a reduced power transfer rate in order to lower the temperature of the BESS, or maintain the temperature of the BESS below a given threshold. For example, the BESS manager may reduce or limit an instantaneous power transfer rate of the BESS such that the average power transfer rate is reduced to the adjusted (reduced) average power transfer rate 457. Accordingly, during a second period 454-2, a BESS charge 415-2 may be operated, which may be less than the BESS charge 415-1.

In some cases, operating the BESS charge 415-2 based on the adjusted average power transfer rate 457 may have the effect of decreasing the output of the genset. For example, the amount of power provided by the genset operating at the efficiency threshold 453, when subtracting the amount of power the BESS charge 415-2 receives, may exceed the power demand 452. Accordingly, in order to meet or match the power demand 452, the genset may be operated at the genset output 413-2, which may be less than the genset output 413-1, and consequently, less than the efficiency threshold 453, for the second period 454-2 (e.g., for an active quantity or configuration of the generators of the genset). In some cases, one or more generators may be taken offline, which may cause the remaining generators to operate above their respective efficiency thresholds. Similar to that described above in connection with FIGS. 4-1, in some cases it may be advantageous to operate the genset outside of the efficiency threshold 453, such as below the efficiency threshold 453 in this case, in order to prioritize the monitoring and controlling of the BESS temperature.

In other examples similar to that of FIGS. 4-1 and 4-2, a BESS manager may identify a temperature of the BESS to be at, past, near, or approaching a lower temperature limit of the BESS. For example, operating the BESS at little or no power output, operating in a colder environment, or other reasons, may cause the BESS to cool down and/or to approach a lower temperature limit. Operating at lower temperatures, in some cases, may be inefficient or harmful to the BESS. Accordingly, the BESS manager may adjust the average power transfer rate of the BESS to an adjusted average power transfer rate, which may be an increased average power transfer rate in order to increase the temperature of the BESS, or to maintain the temperature of the BESS above a given threshold. For example, the BESS manager may increase an instantaneous power transfer rate of the BESS such that the average power transfer rate is increased to the adjusted (increased) average power transfer rate. Additionally, increasing the average power transfer rate of the BESS in this way can have the effect of the genset operating above (e.g., in situations where the genset efficiency threshold is above a power demand) or below (e.g., in situations where the genset efficiency threshold is below a power demand) the efficiency threshold. Nevertheless, as described above, it may be advantageous to prioritize the temperature of the BESS over an efficiency of the genset in order to prevent wear or damage to the BESS.

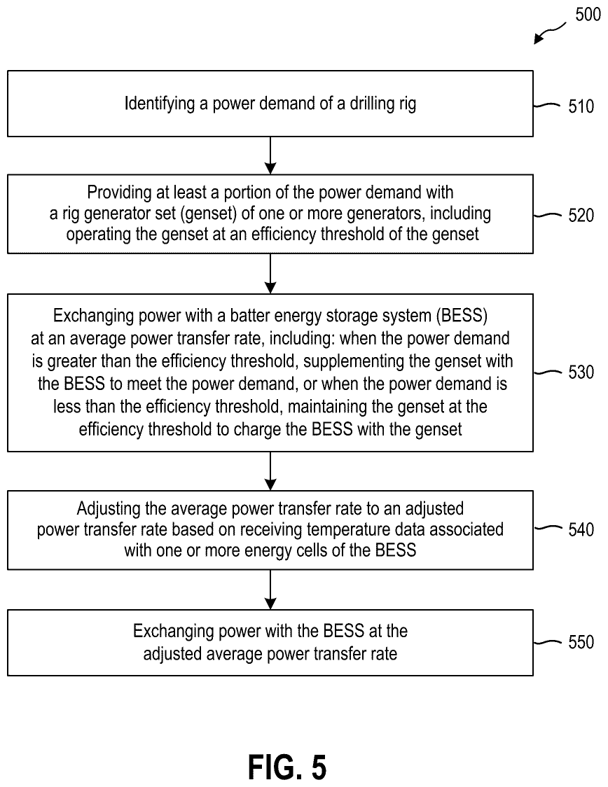

FIG. 5 illustrates a flow diagram for a method 500 or a series of acts for rig power management as described herein, according to at least one embodiment of the present disclosure. While FIG. 5 illustrates acts according to one embodiment, alternative embodiments may add to, omit, reorder, or modify any of the acts of FIG. 5. In some cases, the acts of FIG. 5 are performed as a method. In some cases, a computer system performs the acts of FIG. 5. In some embodiments, the acts of FIG. 5 may be implemented as instructions stored on a computer-readable storage medium.

In some embodiments, the method 500 includes an act 510 of identifying a power demand of a drilling rig.

In some embodiments, the method 500 includes an act 520 of providing at least a portion of the power demand with a rig generator set (genset) of one or more generators, including operating the genset at an efficiency threshold of the genset.

In some embodiments, the method 500 includes an act 530 of exchanging power with a battery energy storage system (BESS) at an average power transfer rate, including: when the power demand is greater than the efficiency threshold, supplementing the genset with the BESS to meet the power demand, or when the power demand is less than the efficiency threshold, maintaining the genset at the efficiency threshold to charge the BESS with the genset.

In some embodiments, the method 500 includes an act 540 of adjusting the average power transfer rate to an adjusted average power transfer rate based on receiving temperature data associated with one or more energy cells of the BESS.

In some embodiments, the method 500 includes an act 550 of exchanging power with the BESS at the adjusted average power transfer rate.

In some embodiments, the method 500 further includes measuring the temperature data at the BESS with one or more temperature sensors. In some embodiments, the temperature data indicates a temperature of the BESS in relation to a threshold temperature. For example, the temperature of the BESS may be a temperature of one or more energy cells of the BESS. The temperature of the BESS may be a temperature of one or more modules of a plurality of energy cells of the BESS. The temperature of the BESS may be a temperature of one or more racks of a plurality of modules of the BESS. In some embodiments, the temperature data further indicates a rate of change of the temperature of the BESS, and the method further includes, when the temperature data indicates the temperature of the BESS approaching the threshold temperature at or above a threshold rate of the change, reducing the average power transfer rate.

In some embodiments, the method 500 further includes, when the temperature of the BESS reaches or exceeds the threshold temperature, reducing the average power transfer rate. In some embodiments, exchanging power with the BESS at the adjusted average power transfer rate further includes operating the genset outside of the efficiency threshold.

In some embodiments, the adjusted average power transfer rate is a reduced average power transfer rate, and the method further includes supplementing the genset with the BESS at the reduced average power transfer rate, and operating the genset above the efficiency threshold. In some embodiments, the adjusted average power transfer rate is a reduced average power transfer rate, and the method further includes charging the BESS at the reduced average power transfer rate and operating the genset below the efficiency threshold. In some embodiments, exchanging power with the BESS at the adjusted average power transfer rate further includes bringing an additional generator of the genset online to meet the power demand.

In some embodiments, the average power transfer rate is monitored over a monitoring period, and exchanging power with the BESS at the average power transfer rate includes exchanging power with the BESS, for at least some of the monitoring period, at an instantaneous power transfer rate that is greater than the average power transfer rate. For example, the instantaneous power transfer rate may be a 3C-rate of the BESS. In some embodiments, the method 500 further includes exchanging power with the BESS, for at least some of the monitoring period, at an instantaneous power transfer rate that is less than the average power transfer rate.

In some embodiments, the average power transfer rate is a C-rate of the BESS of 1.2. in some embodiments, the average power transfer rate is between 200 and 500 kW. In some embodiments, the BESS has an energy storage capacity of between 200 and 500 kWh, and a steady state power demand of the power demand is between 750 kW and 1250 kW. In some cases, when the power demand is greater than the efficiency threshold, the power demand experiences a transient increase of up to 1.5 MW. In some embodiments, the method 500 further includes operating the genset at the efficiency threshold and supplementing the genset with the BESS to meet the transient increase in the power demand.

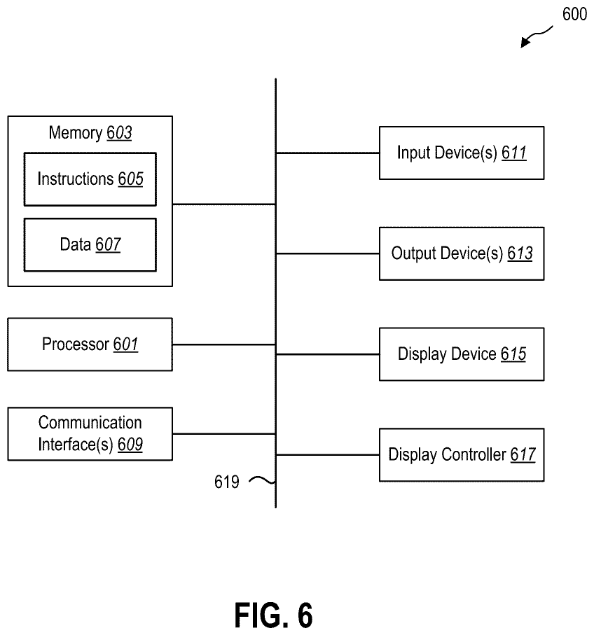

FIG. 6 illustrates certain components that may be included within a computer system 600. One or more computer systems 600 may be used to implement the various devices, components, and systems described herein.

The computer system 600 includes a processor 601. The processor 601 may be a general-purpose single or multi-chip microprocessor (e.g., an Advanced RISC (Reduced Instruction Set Computer) Machine (ARM)), a special purpose microprocessor (e.g., a digital signal processor (DSP)), a microcontroller, a programmable gate array, etc. The processor 601 may be referred to as a central processing unit (CPU). Although just a single processor 601 is shown in the computer system 600 of FIG. 6, in an alternative configuration, a combination of processors (e.g., an ARM and DSP) could be used.

The computer system 600 also includes memory 603 in electronic communication with the processor 601. The memory 603 may be any electronic component capable of storing electronic information. For example, the memory 603 may be embodied as random access memory (RAM), read-only memory (ROM), magnetic disk storage media, optical storage media, flash memory devices in RAM, on-board memory included with the processor, erasable programmable read-only memory (EPROM), electrically erasable programmable read-only memory (EEPROM) memory, registers, and so forth, including combinations thereof.

Instructions 605 and data 607 may be stored in the memory 603. The instructions 605 may be executable by the processor 601 to implement some or all of the functionality disclosed herein. Executing the instructions 605 may involve the use of the data 607 that is stored in the memory 603. Any of the various examples of modules and components described herein may be implemented, partially or wholly, as instructions 605 stored in memory 603 and executed by the processor 601. Any of the various examples of data described herein may be among the data 607 that is stored in memory 603 and used during execution of the instructions 605 by the processor 601.

A computer system 600 may also include one or more communication interfaces 609 for communicating with other electronic devices. The communication interface(s) 609 may be based on wired communication technology, wireless communication technology, or both. Some examples of communication interfaces 609 include a Universal Serial Bus (USB), an Ethernet adapter, a wireless adapter that operates in accordance with an Institute of Electrical and Electronics Engineers (IEEE) 802.11 wireless communication protocol, a Bluetooth^{®}wireless communication adapter, and an infrared (IR) communication port.

A computer system 600 may also include one or more input devices 611 and one or more output devices 613. Some examples of input devices 611 include a keyboard, mouse, microphone, remote control device, button, joystick, trackball, touchpad, and lightpen. Some examples of output devices 613 include a speaker and a printer. One specific type of output device that is typically included in a computer system 600 is a display device 615. Display devices 615 used with embodiments disclosed herein may utilize any suitable image projection technology, such as liquid crystal display (LCD), light-emitting diode (LED), gas plasma, electroluminescence, or the like. A display controller 617 may also be provided, for converting data 607 stored in the memory 603 into text, graphics, and/or moving images (as appropriate) shown on the display device 615.

The various components of the computer system 600 may be coupled together by one or more buses, which may include a power bus, a control signal bus, a status signal bus, a data bus, etc. For the sake of clarity, the various buses are illustrated in FIG. 6 as a bus system 619.

The embodiments of the rig power management system have been primarily described with reference to wellbore drilling operations; the rig power management system described herein may be used in applications other than the drilling of a wellbore. In other embodiments, rig power management system according to the present disclosure may be used outside a wellbore or other downhole environment used for the exploration or production of natural resources. For instance, rig power management system of the present disclosure may be used in a borehole used for placement of utility lines. Accordingly, the terms “wellbore,” “borehole” and the like should not be interpreted to limit tools, systems, assemblies, or methods of the present disclosure to any particular industry, field, or environment.

One or more specific embodiments of the present disclosure are described herein. These described embodiments are examples of the presently disclosed techniques. Additionally, in an effort to provide a concise description of these embodiments, not all features of an actual embodiment may be described in the specification. It should be appreciated that in the development of any such actual implementation, as in any engineering or design project, numerous embodiment-specific decisions will be made to achieve the developers' specific goals, such as compliance with system-related and business-related constraints, which may vary from one embodiment to another. Moreover, it should be appreciated that such a development effort might be complex and time consuming, but would nevertheless be a routine undertaking of design, fabrication, and manufacture for those of ordinary skill having the benefit of this disclosure.

Additionally, it should be understood that references to “one embodiment” or “an embodiment” of the present disclosure are not intended to be interpreted as excluding the existence of additional embodiments that also incorporate the recited features. For example, any element described in relation to an embodiment herein may be combinable with any element of any other embodiment described herein. Numbers, percentages, ratios, or other values stated herein are intended to include that value, and also other values that are “about” or “approximately” the stated value, as would be appreciated by one of ordinary skill in the art encompassed by embodiments of the present disclosure. A stated value should therefore be interpreted broadly enough to encompass values that are at least close enough to the stated value to perform a desired function or achieve a desired result. The stated values include at least the variation to be expected in a suitable manufacturing or production process, and may include values that are within 5%, within 1%, within 0.1%, or within 0.01% of a stated value.

A person having ordinary skill in the art should realize in view of the present disclosure that equivalent constructions do not depart from the spirit and scope of the present disclosure, and that various changes, substitutions, and alterations may be made to embodiments disclosed herein without departing from the spirit and scope of the present disclosure. Equivalent constructions, including functional “means-plus-function” clauses are intended to cover the structures described herein as performing the recited function, including both structural equivalents that operate in the same manner, and equivalent structures that provide the same function. It is the express intention of the applicant not to invoke means-plus-function or other functional claiming for any claim except for those in which the words ‘means for’ appear together with an associated function. Each addition, deletion, and modification to the embodiments that falls within the meaning and scope of the claims is to be embraced by the claims.

The terms “approximately,” “about,” and “substantially” as used herein represent an amount close to the stated amount that is within standard manufacturing or process tolerances, or which still performs a desired function or achieves a desired result. For example, the terms “approximately,” “about,” and “substantially” may refer to an amount that is within less than 5% of, within less than 1% of, within less than 0.1% of, and within less than 0.01% of a stated amount. Further, it should be understood that any directions or reference frames in the preceding description are merely relative directions or movements. For example, any references to “up” and “down” or “above” or “below” are merely descriptive of the relative position or movement of the related elements.

The present disclosure may be embodied in other specific forms without departing from its spirit or characteristics. The described embodiments are to be considered as illustrative and not restrictive. The scope of the disclosure is, therefore, indicated by the appended claims rather than by the foregoing description. Changes that come within the meaning and range of equivalency of the claims are to be embraced within their scope.

What is claimed is:

1. A method for rig power management, comprising:
identifying a power demand of a drilling rig;
providing at least a portion of the power demand with a rig generator set (genset) of one or more generators, including operating the genset at an efficiency threshold of the genset;
exchanging power with a battery energy storage system (BESS) at an average power transfer rate, including:
when the power demand is greater than the efficiency threshold, supplementing the genset with the BESS to meet the power demand; or
when the power demand is less than the efficiency threshold, maintaining the genset at the efficiency threshold to charge the BESS with the genset;
adjusting the average power transfer rate to an adjusted average power transfer rate based on receiving temperature data associated with one or more energy cells of the BESS; and
exchanging power with the BESS at the adjusted average power transfer rate.

2. The method of claim 1, further comprising measuring the temperature data at the BESS with one or more temperature sensors.

3. The method of claim 1, wherein the temperature data indicates a temperature of the BESS in relation to a threshold temperature, and wherein the temperature of the BESS is one or more of:
a temperature of one or more energy cells of the BESS;
a temperature of one or more modules of a plurality of energy cells of the BESS; or
a temperature of one or more racks of a plurality of modules of the BESS.

4. The method of claim 3, further comprising, when the temperature of the BESS reaches or exceeds the threshold temperature, reducing the average power transfer rate.

5. The method of claim 3, wherein the temperature data further indicates a rate of change of the temperature of the BESS, and further comprising, when the temperature data indicates the temperature of the BESS approaching the threshold temperature at or above a threshold rate of the change, reducing the average power transfer rate.

6. The method of claim 1, wherein exchanging power with the BESS at the adjusted average power transfer rate further includes operating the genset outside of the efficiency threshold.

7. The method of claim 6, wherein the adjusted average power transfer rate is a reduced average power transfer rate, and further comprising supplementing the genset with the BESS at the reduced average power transfer rate, and operating the genset above the efficiency threshold.

8. The method of claim 6, wherein the adjusted average power transfer rate is a reduced average power transfer rate, and further comprising charging the BESS at the reduced average power transfer rate and operating the genset below the efficiency threshold.

9. The method of claim 6, wherein exchanging power with the BESS at the adjusted average power transfer rate further includes bringing an additional generator of the genset online to meet the power demand.

10. The method of claim 1, wherein the average power transfer rate is monitored over a monitoring period, and exchanging power with the BESS at the average power transfer rate includes exchanging power with the BESS, for at least some of the monitoring period, at an instantaneous power transfer rate that is greater than the average power transfer rate.

11. The method of claim 10, wherein the instantaneous power transfer rate is a 3C-rate of the BESS.

12. The method of claim 10, further comprising exchanging power with the BESS, for at least some of the monitoring period, at an instantaneous power transfer rate that is less than the average power transfer rate.

13. The method of claim 10, wherein the average power transfer rate is a C-rate of the BESS of 1.2.

14. The method of claim 1, wherein the average power transfer rate is between 200 and 500 kW.

15. The method of claim 1, wherein:
the BESS has an energy storage capacity of between 200 and 500 kWh;
a steady state power demand of the power demand is between 750 kW and 1250 kW; and
when the power demand is greater than the efficiency threshold, the power demand experiences a transient increase of up to 1.5 MW;
further comprising, operating the genset at the efficiency threshold and supplementing the genset with the BESS to meet the transient increase in the power demand.

16. A rig power management system, comprising:
a drilling rig having one or more electronic components for performing drilling operations based on a power demand of the drilling rig;
a rig generator set (genset) of one or more generators;
a battery energy storage system (BESS);
a processor;
a memory in electronic communication with the processor; and
instructions stored in the memory which, when executed by the processor, cause the processor to:
identify the power demand of the drilling rig;
provide at least a portion of the power demand with the genset, including operating the genset at an efficiency threshold of the genset;
exchange power with the BESS at an average power transfer rate, including:
when the power demand is greater than the efficiency threshold, supplementing the genset with the BESS to meet the power demand; or
when the power demand is less than the efficiency threshold, maintaining the genset at the efficiency threshold to charge the BESS with the genset;
adjust the average power transfer rate to an adjusted average power transfer rate based on receiving temperature data associated with one or more energy cells of the BESS; and
exchange power with the BESS at the adjusted average power transfer rate.

17. The rig power management system of claim 16, wherein the temperature data indicates a temperature of the BESS in relation to a threshold temperature, and wherein the temperature of the BESS is one or more of:
a temperature of one or more energy cells of the BESS;
a temperature of one or more modules of a plurality of energy cells of the BESS; or
a temperature of one or more racks of a plurality of modules of the BESS.

18. The rig power management system of claim 17, wherein the temperature data further indicates a rate of change of the temperature of the BESS, and further comprising:
when the temperature of the BESS reaches or exceeds the threshold temperature, reducing the average power transfer rate; and
when the temperature data indicates the temperature of the BESS approaching the threshold temperature at or above a threshold rate of the change, reducing the average power transfer rate.

19. A computer-readable storage medium having instructions stored thereon, the instructions being executable by a processor to cause the processor to:
identify a power demand of a drilling rig;
provide at least a portion of the power demand with a rig generator set (genset), including operating the genset at an efficiency threshold of the genset;
exchange power with a battery energy storage system (BESS) at an average power transfer rate, including:
when the power demand is greater than the efficiency threshold, supplementing the genset with the BESS to meet the power demand; or
when the power demand is less than the efficiency threshold, maintaining the genset at the efficiency threshold to charge the BESS with the genset;
adjust the average power transfer rate to an adjusted average power transfer rate based on receiving temperature data associated with one or more energy cells of the BESS; and
exchange power with the BESS at the adjusted average power transfer rate.

20. The computer-readable storage medium of claim 19, wherein the adjusted average power transfer rate is a reduced average power transfer rate, and exchanging power with the BESS at the adjusted average power transfer rate further includes:
when the power demand is greater than the efficiency threshold, supplementing the genset with the BESS at the reduced average power transfer rate, and operating the genset above the efficiency threshold; or
when the power demand is less than the efficiency threshold, charging the BESS at the reduced average power transfer rate and operating the genset below the efficiency threshold.
